(19) United States
(12) Patent Application Publication
(10) Pub. No.: US 2023/0245870 A1
(43) Pub. Date: Aug. 3, 2023

(54) PLASMA PROCESSING APPARATUS AND PLASMA PROCESSING METHOD

(71) Applicant: Tokyo Electron Limited, Tokyo (JP)

(72) Inventors: Taro IKEDA, Nirasaki City (JP); Hiroyuki MATSUURA, Oshu City (JP); Satoru KAWAKAMI, Nirasaki City (JP)

(21) Appl. No.: 18/101,676

(22) Filed: Jan. 26, 2023

(30) Foreign Application Priority Data
Feb. 2, 2022 (JP) 2022-015012

(51) Int. Cl. H01J 37/32; C23C 16/455; C23C 16/46

(52) U.S. Cl. CPC H01J 37/32724; H01J 37/32568; H01J 37/32174; H01J 37/32541; C23C 16/45536; C23C 16/46; H01J 2237/201; H01J 2237/20235; H01J 2237/332

(57) ABSTRACT

A plasma processing apparatus includes: a substrate holder configured to place a plurality of substrates in a multi-stage structure in a height direction on the substrate holder; and a processing container in which the substrate holder is accommodated and including a heating part that heats the plurality of substrates, wherein the substrate holder is provided with a plurality of stages made of a dielectric material, and a first electrode layer and a second electrode layer embedded in the plurality of stages.

### CROSS-REFERENCE TO RELATED APPLICATION

This application is based upon and claims the benefit of priority from Japanese Patent Application No. 2022-015012, filed on Feb. 2, 2022, the entire contents of which are incorporated herein by reference.

### TECHNICAL FIELD

The present disclosure relates to a plasma processing apparatus and a plasma processing method.

### BACKGROUND

For example, Patent Document 1 discloses a batch type apparatus that supplies a gas into a reaction tube and activates the gas by a magnetic field component generated from an antenna to generate plasma, thereby processing a plurality of substrates at once.

### PRIOR ART DOCUMENTS

### Patent Documents

Patent Document 1: Japanese Patent Laid-Open Publication No. 2014-093226

### SUMMARY

According to one embodiment of the present disclosure, there is provided a plasma processing apparatus including: a substrate holder configured to place a plurality of substrates in a multi-stage structure in a height direction on the substrate holder; and a processing container in which the substrate holder is accommodated and including a heating part that heats the plurality of substrates, wherein the substrate holder includes a plurality of stages, which are made of a dielectric material, and a first electrode layer and a second electrode layer embedded in the plurality of stages.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic diagram illustrating a configuration example of a plasma processing apparatus according to a first embodiment.

FIG. 2 is a schematic cross-sectional view illustrating an example of a substrate holder according to an embodiment.

FIG. 3 is an enlarged view of a portion of the substrate holder illustrated in FIG. 2.

FIGS. 4A and 4B are schematic cross-sectional views illustrating an example of a stage of the substrate holder illustrated in FIG. 2.

FIGS. 5A to 5C are schematic cross-sectional views of the stage.

FIGS. 6A and 6B are cross-sectional views of a portion of a post member according to an embodiment.

FIG. 7 is a schematic diagram illustrating a configuration example of a plasma processing apparatus according to a second embodiment.

FIG. 8 is a cross-sectional view of the plasma processing apparatus illustrated in FIG. 7.

### DETAILED DESCRIPTION

Hereinafter, embodiments for carrying out the present disclosure will be described with reference to the drawings. In each drawing, the same components will be denoted by the same reference numerals, and redundant explanations thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In this specification, in the directions of parallel, right angle, orthogonal, horizontal, vertical, up/down, left/right, and the like, a deviation that does not impair the effect of an embodiment is allowed. The shape of a corner is not limited to a right angle but may be rounded in an arch shape. The terms parallel, right-angled, orthogonal, horizontal, vertical, circular, cylindrical, disk, and coincident may include approximately parallel, approximately right-angled, approximately orthogonal, approximately horizontal, approximately vertical, approximately circular, approximately cylindrical, approximately disk, and approximately coincident.

In a processing container of a plasma processing apparatus, an atomic layer deposition (ALD) process, a chemical vapor deposition (CVD) process, or the like is performed so that a desired film is formed on a substrate. By the way, there are increasing operations of performing the ALD process with the miniaturization of semiconductor devices formed on the substrate. While the ALD process may form the film uniformly, it has a lower film formation rate than that of the CVD process, resulting in a reduction in productivity. In order to compensate for such a reduction in productivity, there has been proposed a method of generating plasma using RF power in the vicinity of a batch type processing container, or generating plasma in an upper portion of a rotary semi-batch type plasma processing apparatus that processes several substrates at the same time.

For example, even in a batch type plasma processing apparatus that processes several to several tens of substrates collectively, it is important to perform more precise plasma control. Accordingly, there is a demand for a highly productive apparatus that has a plasma processing performance using RF power equivalent to that of a single wafer type apparatus that processes substrates one by one.

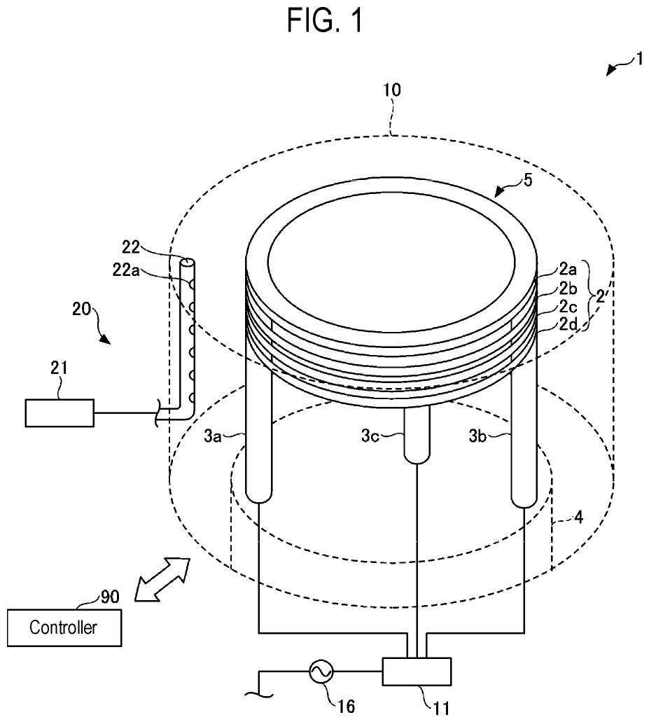

Therefore, the present embodiment proposes a batch type plasma processing apparatus 1 capable of supplying RF power to an electrode layer embedded in a stage 2 (see FIG. 1) to perform precise plasma control.

### First Embodiment

### [Plasma Processing Apparatus]

First, a configuration example of the plasma processing apparatus 1 according to a first embodiment will be described with reference to FIG. 1. FIG. 1 is a schematic diagram illustrating the configuration example of the plasma processing apparatus 1 according to the first embodiment.

The plasma processing apparatus 1 includes a processing container 10, a gas supplier 20, an exhaust device (not illustrated), a controller 90, and the like.

The processing container 10 has a substantially cylindrical shape. The processing container 10 includes a substrate holder 5 and a pedestal 4. The processing container 10 accommodates the substrate holder 5, and includes a heating part (not illustrated) such as, for example, a heater that heats a substrate which is, for example, a semiconductor wafer. During a plasma processing of the substrate, the interior of the processing container 10 may be heated to about 700 degrees C. to 800 degrees C. by the heating part. The processing container 10, the substrate holder 5, and the pedestal 4 are made of a heat-resistant material such as, for example, quartz.

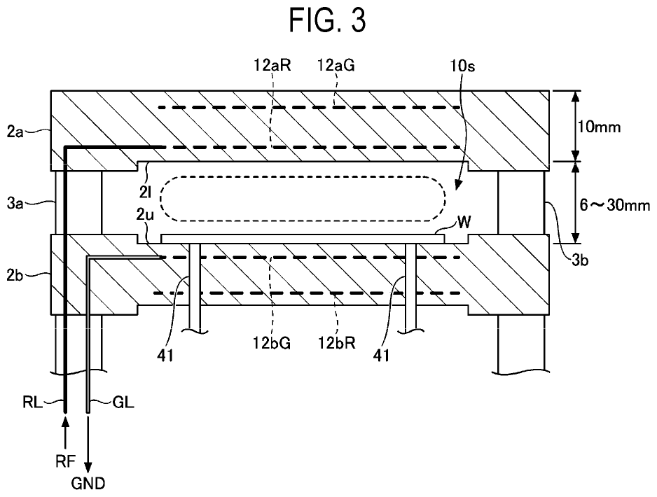

The substrate holder 5 includes stages 2 arranged in a multi-stage structure in a height direction. In the present embodiment, the stages 2 include stages 2a, 2b, 2c, and 2d. Plasma processing spaces 10s (see FIG. 3) are provided between the stage 2a and the stage 2b, between the stage 2b and the stage 2c, and between the stage 2c and the stage 2d, respectively. The substrate holder 5 may place a plurality of substrates on the stages 2b, 2c, and 2d. The stages 2 are formed of a dielectric material such as quartz. The substrate holder 5 is provided with three post members 3a, 3b, and 3c on an outer periphery thereof. The three post members 3a, 3b, and 3c are arranged at an equal interval in a circumferential direction of the stages 2 to support the stages 2. The post members 3a, 3b and 3c are fixed to the pedestal 4. The pedestal 4 is rotatable during the plasma processing of the substrate.

A gas supply pipe 22 extends horizontally to pass through the processing container 10 and is bent in an L shape within the processing container 10 to extend upward. The gas supplier 20 allows a processing gas output from a gas source 21 to flow through the gas supply pipe 22, thereby supplying the processing gas into the processing container 10 from a plurality of gas holes 22a which are arranged vertically. In this way, the processing gas is discharged from outer peripheral sides of the plurality of substrates W in a side flow manner by rotating the substrate holder 5 on which the plurality of substrates W are placed, so that films are formed on the plurality of substrates W at the same time.

The processing gas includes, for example, a film forming gas, a cleaning gas, and a purge gas. In addition, the example of FIG. 1 illustrates a case where there is one gas supply pipe 22, but a plurality of gas supply pipes 22 may be provided.

The interior of the processing container 10 is exhausted by the exhaust device such as a dry pump, a turbo molecular pump, or the like. The controller 90 controls an operation of the plasma processing apparatus 1. The controller 90 may be, for example, a computer. A computer program that controls the entire operation of the plasma processing apparatus 1 may be stored in a non-transitory computer-readable storage medium. The storage medium may be, for example, a flexible disk, a compact disk, a hard disk, a flash memory, a DVD, or the like.

As illustrated in FIG. 1, RF power output from a radio frequency (RF) power supply 16 is distributed by a distributor 11. The distributed RF power is supplied to each of a plurality of first electrode layers embedded in the plurality of stages 2 via feeder lines accommodated inside the post members 3a, 3b, and 3c (hereinafter collectively referred to as the post member 3).

The stages 2a, 2b, 2c, and 2d are circular with the same diameter and have the same central axis. The stages 2a, 2b, 2c, and 2d are stacked one above another in the height direction at predetermined intervals. Since the interior of the processing container 10 is under an environment of 800 degrees C. to 900 degrees C., the stages 2a, 2b, 2c, and 2d may be made of quartz which has the highest thermal durability.

### [Substrate Holder]

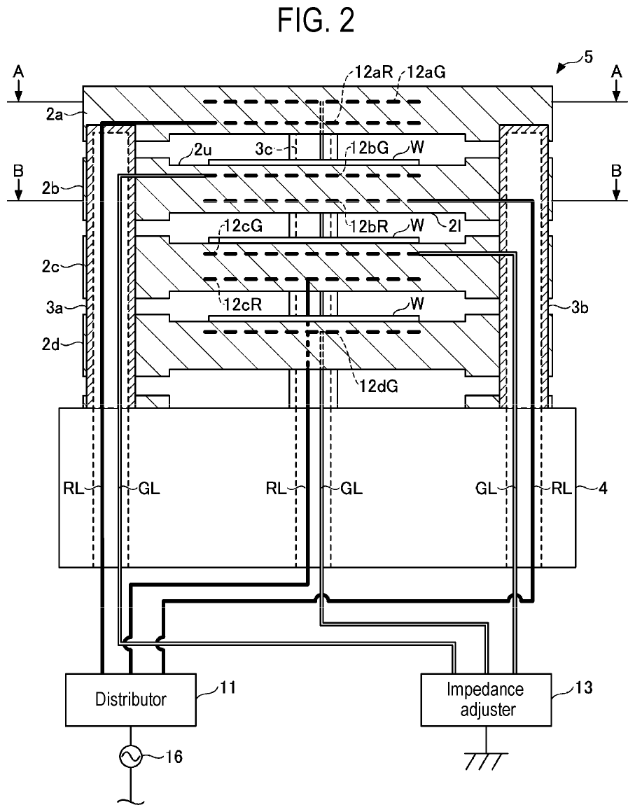

FIG. 2 is a cross-sectional view of the substrate holder 5 taken vertically along a plane passing through the central axis of the stage 2. An electrode layer is embedded in the stage 2. A second electrode layer 12aG and a first electrode layer 12aR are embedded one above another in the uppermost stage 2a. The second electrode layer 12aG is an example of a second electrode layer connected to a ground line GL. The first electrode layer 12aR is an example of a first electrode layer connected to a feeder line RL that supplies RF power. Among the quartz post members 3a, 3b, and 3c that fix the stage 2, the second electrode layer 12aG is connected to the ground line GL accommodated in a cavity in the post member 3c, and the first electrode layer 12aR is connected to the feeder line RL accommodated in a cavity in the post member 3a.

A second electrode layer 12bG and a first electrode layer 12bR are embedded one above another in the second stage 2b from the top. The second electrode layer 12bG is an example of the second electrode layer connected to the ground line GL. The first electrode layer 12bR is an example of the first electrode layer connected to the feeder line RL that supplies RF power. The second electrode layer 12bG is connected to the ground line GL accommodated in the cavity in the post member 3a, and the first electrode layer 12bR is connected to the feeder line RL accommodated in a cavity in the post member 3b.

A second electrode layer 12cG and a first electrode layer 12cR are embedded one above another in the third stage 2c from the top. The second electrode layer 12cG is an example of the second electrode layer connected to the ground line GL. The first electrode layer 12cR is an example of the first electrode layer connected to the feeder line RL that supplies RF power. The second electrode layer 12cG is connected to the ground line GL accommodated in the cavity in the post member 3b, and the first electrode layer 12cR is connected to the feeder line RL accommodated in the cavity in the post member 3c.

A second electrode layer 12dG is embedded in the lowermost stage 2d on the side of a substrate placement surface. The second electrode layer 12dG is an example of the second electrode layer connected to the ground line GL. No first electrode layer is provided in the stage 2d. The second electrode layer 12dG is connected to the ground line GL accommodated in the cavity in the post member 3c.

Among the electrode layers embedded in the plurality of stages 2a to 2d of the substrate holder 5, the electrode layer (second electrode layer 12aG) at the top (the upper side of the processing container 10) and the electrode layer (second electrode layer 12dG) at the bottom (the lower side of the processing container 10) are second electrode layers connected to a ground. In this way, the electrode layers provided at the top and bottom of the stages 2 function as a shield by being connected to the ground, thereby preventing plasma from being generated between the stages 2 and the processing container 10. In order to exhibit such a shield function, the second electrode layer 12aG is arranged above the first electrode layer 12aR in the uppermost stage 2a.

Inside at least one of the plurality of post members 3a, 3b, and 3c, the ground line GL may accommodate a ground line connected to at least one of the second electrode layers 12aG, 12bG, 12cG, and 12dG in the plurality of stages 2. When the ground line GL is accommodated in only one of the post members 3, the second electrode layers 12aG, 12bG, 12cG, and 12dG are all connected to the ground line GL accommodated in the same post member 3.

A shallow circular recess is formed in the upper surface of the stage 2. The bottom of the recess serves as a placement surface 2u on which the substrate W is placed. The placement surface 2u is circular, and has a diameter larger than a diameter of the substrate W. The lower surface of the stage 2 also has a circular recess with the same size as the recess on the upper surface at a position opposite to the recess on the upper surface. The bottom (bottom surface 21) of the recess on the lower surface is circular. Thus, a space that functions as the plasma generation space 10s (see FIG. 3) is formed between adjacent stages 2.

For example, the first electrode layer 12bR in the stage 2b (an example of a first stage) among the plurality of stages 2 is arranged opposite to the second electrode layer 12cG in the stage 2c (an example of a second stage) adjacent to the stage 2b with the plasma processing space 10s interposed therebetween. The second electrode layer 12bG in the stage 2b is arranged opposite to the first electrode layer 12aR in the stage 2a (an example of a third stage) adjacent to the stage 2b with the plasma processing space 10s interposed therebetween.

RF power is supplied to the first electrode layers 12aR, 12bR, and 12cR (hereinafter collectively also referred to as the first electrode layer 12R). The RF power output from the RF power supply 16 is distributed by the distributor 11 and supplied to the first electrode layers 12aR, 12bR, and 12cR in the plurality of stages 2a, 2b, and 2c, respectively.

The second electrode layers 12aG, 12bG, 12cG, and 12dG (hereinafter collectively also referred to as the second electrode layer 12G) are connected to the ground via an impedance adjuster 13. However, the second electrode layers 12aG, 12bG, 12cG, and 12dG may be directly connected to the ground without passing through the impedance adjuster 13.

With the above configuration, RF power is supplied to each first electrode layer 12R in the stage 2, thereby generating an electric field in the stage 2. The second electrode layer 12G in the stage 2 opposite to each first electrode layer 12R is at the ground potential, and a discharge phenomenon occurs in each plasma processing space 10s (see FIG. 3), so that plasma is generated in each plasma processing space 10s. FIG. 3 is an enlarged view of a portion of the substrate holder 5 illustrated in FIG. 2. Plasma indicated by a dotted line is generated in the plasma processing space 10s between the stage 2a and the stage 2b. The plasma generated in the plasma processing space 10s below the stage 2b is omitted.

In the example of FIG. 3, RF power is supplied to the first electrode layer 12aR. Thus, plasma is generated in the plasma processing space 10s between the stage 2a and the stage 2b, so that a plasma processing is performed on the substrate W placed on the placement surface 2u of the stage 2b.

Similarly, RF power is supplied to the first electrode layer 12bR. Thus, plasma is generated in the plasma processing space (see FIG. 2) between the stage 2b and the stage 2c, so that the plasma processing is performed on the substrate W placed on the placement surface 2u of the stage 2c.

Similarly, RF power is supplied to the first electrode layer 12cR. Thus, plasma is generated in the plasma processing space (see FIG. 2) between the stage 2c and the stage 2d, so that the plasma processing is performed on the substrate W placed on the placement surface 2u of the stage 2d.

With this configuration, it is possible to provide the plasma processing apparatus 1 which has a plasma processing performance with high in-plane uniformity using RF power equivalent to that of a single-wafer type plasma processing apparatus that processes substrates one by one, and which has high productivity by simultaneously performing film formation on a plurality of substrates W collectively.

The substrate holder 5 includes a lift pin mechanism 41 for transferring the substrate W to each of the stages 2b to 2d. FIG. 3 illustrates only the lift pin mechanism 41 for transferring the substrate W onto the stage 2b. The lift pin mechanism 41 has a function of raising and lowering lift pins, and is configured to raise the substrate W from the back side of the substrate W by the respective lift pins passing through the stages 2b to 2d to transfer the substrate W to a transfer arm or to place the substrate W on the placement surface 2u.

A thickness from the placement surface 2u of each stage 2 to the bottom surface 21 of the recess on the lower surface of each stage 2 is about 10 mm. The upper surface of the uppermost stage 2a among the stages 2 may have no recess and placement surface. In this case, the thickness from the upper surface of the stage 2a to the bottom surface 21 on the lower surface is, for example, about 10 mm. A height of the plasma processing space 10s between adjacent stages 2, that is, a distance from the bottom surface 21 of one stage 2 to the placement surface 2u of the adjacent underlying stage 2 is, for example, about 6 mm to 30 mm.

The lift pin mechanism 41 is provided in each stage 2, so that the substrate W is loaded and unloaded by the lift pins. Therefore, the post members 3a, 3b, and 3c are arranged at intervals that may ensure a width required to horizontally take out the substrate W raised by the lift pin mechanism 41. Further, as illustrated in FIG. 2, the post members 3a, 3b, and 3c extend in the height direction from the outer peripheral side of the placement surface 2u, and pass through all of the stages 2 from the uppermost stage 2a to the lowermost stage 2d. The post members 3a, 3b and 3c are made of a dielectric material such as quartz and are hollow.

### [Electrode Layer]

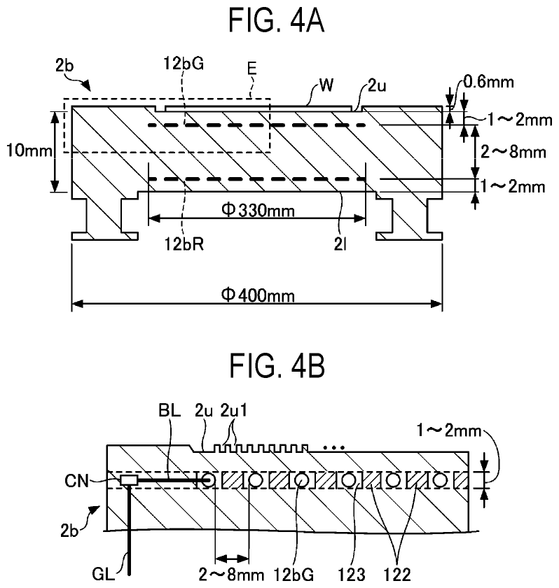

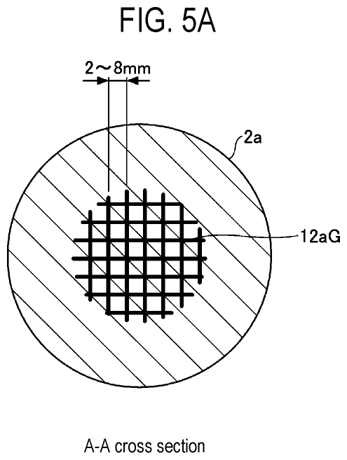

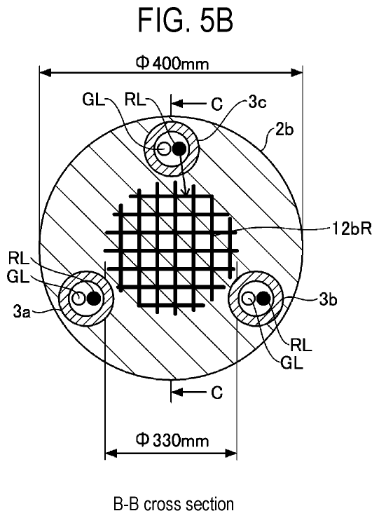

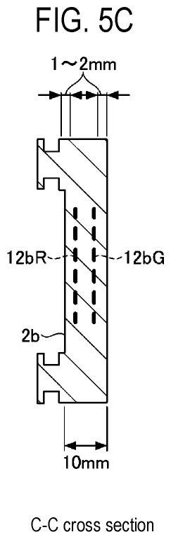

Next, the first electrode layer 12R and the second electrode layer 12G will be described in more detail with reference to FIGS. 4A to 5C. FIG. 4A is a schematic cross-sectional view illustrating the stage 2b as an example of the stage 2 in an enlarged scale. FIG. 4B is an enlarged view of region E of FIG. 4A. FIG. 5A is a cross-sectional view taken along A-A of FIG. 2, and FIG. 5B is a cross-sectional view taken along B-B of FIG. 2. FIG. 5C is a cross-sectional view taken along C-C of FIG. 5B.

As illustrated in FIGS. 4A to 5C, the first electrode layer 12bR and the like and the second electrode layers 12aG and 12bG and the like are mesh-shaped electrodes, and electrode lines are arranged in a grid pattern. The interval between adjacent electrode lines is, for example, 2 mm to 8 mm. Both the first electrode layer and the second electrode layer may be mesh-shaped electrodes as in the present embodiment, but one may be a mesh-shaped electrode and the other may be a film-shaped electrode. Both the first electrode layer 12R and the second electrode layer 12G have circular outer edges and have the same size.

As illustrated in FIGS. 4A and 5B, the diameter φ of the circular stage 2 is, for example, 400 mm. The size of the outer edge portions of the first electrode layer 12R and the second electrode layer 12G may be larger than that of the placement surface 2u, or may be substantially the same. In the example illustrated in FIG. 4A, the diameter φ of the first electrode layer 12R and the second electrode layer 12G is 330 mm, and the diameter φ of the placement surface 2u is about 302 mm. The size of the outer edge portions of the first electrode layer 12R and the second electrode layer 12G is larger than that of the placement surface 2u.

The depth from the upper surface of the stage 2b to the placement surface 2u is about 0.6 mm. The distance from the placement surface 2u to the second electrode layer 12bG is 1 mm to 2 mm in the thickness direction of the stage 2b. The distance from the second electrode layer 12bG to the first electrode layer 12bR in the thickness direction is 2 mm to 8 mm. The thickness from the first electrode layer 12bR to the bottom surface 21 of the stage 2b is 1 mm to 2 mm.

Referring to FIG. 4B which is an enlarged view of region E of FIG. 4A, a pillar 122 made of a dielectric material is arranged in each gap 123 between the mesh-shaped (grid-shaped) electrode lines of the second electrode layer 12bG. The pillar 122 is made of, for example, quartz. The pillar 122 is fixed between quartz of the stage 2b.

The second electrode layer 12bG is made of a metal, and the stage 2b is made of quartz. Therefore, when the temperature of the substrate holder 5 reaches a high temperature of 500 degrees C. to 700 degrees C. or higher during the plasma processing of the substrate W, stress is applied to the stages 2 sandwiching the first electrode layer 12R and the second electrode layer 12G therebetween due to a difference in thermal expansion between the second electrode layer 12bG and the stage 2b. On the other hand, the stress applied to the stages 2 may be alleviated by providing the pillar 122 in the gap 123.

The height of the pillar 122 is 1 mm to 2 mm. As described above, the interval between adjacent electrode lines of the second electrode layer 12bG is 2 mm to 8 mm. Similarly to the second electrode layer 12G, the first electrode layer 12R has the quartz pillar 122 arranged in the gap 123 between mesh-shaped electrode lines when the electrode layer has a mesh shape.

In addition, as illustrated in FIG. 4B, the second electrode layer 12bG is connected to an electrode leading line BL and is connected to the ground line GL via a connection portion CN. The first electrode layer 12bR is connected to an electrode leading line (not illustrated) and is connected to the feeder line RL via a connection portion. In FIGS. 4A and 4B, the post member 3 accommodating the ground line GL and the feeder line RL is omitted. Fine protrusions 2u1 are formed on the placement surface 2u by embossing, and the substrate W is placed on the protrusions 2u1.

The RF power distributed by the distributor 11 and supplied to the first electrode layer 12R of each stage 2 is approximately 200 W to 300 W but is not limited thereto.

As illustrated in FIG. 5B, power is supplied to the first electrode layer 12bR from one end of the mesh-shaped electrode lines. The supply of power to another first electrode layer 12R is also the same. In the present embodiment, one feeder line RL and one ground line GL are accommodated in any one of the post members 3a, 3b, and 3c. Each feeder line RL is connected to any one of the first electrode layers 12aR, 12bR, and 12cR, and each ground line GL is connected to at least one of the second electrode layers 12aG, 12bG, 12cG, and 12dG. The ground line GL may be accommodated in any one of the post members 3a, 3b, and 3c.

Any one of the post members 3 may accommodate a plurality of feeder lines RL and/or ground lines GL. Any one of the post members 3 may not accommodate the feeder RL and/or the ground line GL.

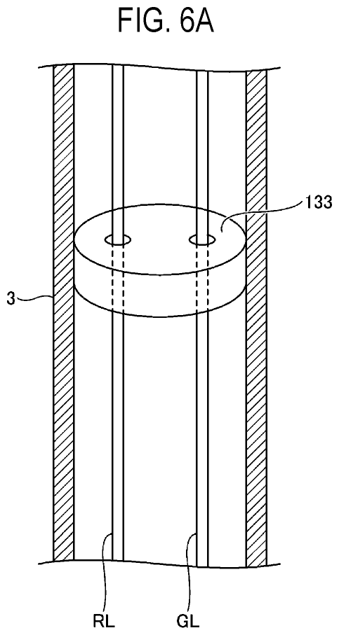

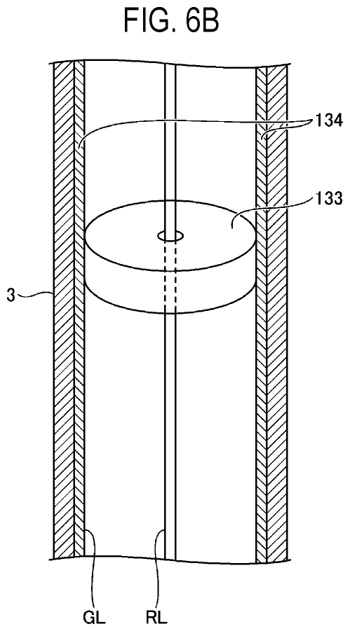

FIGS. 6A and 6B are cross-sectional views of a portion of the post member 3 according to an embodiment. The interior of the post member 3 is a cavity, and in the example of FIG. 6A, the inner wall of the post member 3 exposes quartz. In the example of FIG. 6B, the inner wall of the post member 3 is covered with a metal film or metal cylindrical member 134. The metal film or metal cylindrical member 134 may be connected to the ground, thus functioning as the ground line GL for grounding each second electrode layer 12G in the stage 2.

In the example of FIG. 6A, one feeder line RL and one ground line GL are accommodated in the quartz post member 3. The feeder line RL and the ground line GL pass through a quartz fixing member 133. The feeder line RL and the ground line GL are arranged without coming into contact with the fixing member 133.

In the example of FIG. 6B, the metal film or metal cylindrical member 134 serves as the ground line GL, so that only the feeder line RL is arranged in the post member 3. A radio frequency-shielded coaxial structure may be formed by the central feeder line RL and the outer metal film or metal cylindrical member 134 (ground line GL). The feeder line RL passes through the quartz fixing member 133. Thus, the feeder line RL is arranged without coming into contact with the metal film or metal cylindrical member 134 at the ground potential. In addition, in order to prevent electrical shorts, the feeder line RL itself may be covered with a cylinder made of ceramics such as quartz.

The impedance adjuster 13 (see FIG. 2) is provided on the ground line GL. The RF power output from the RF power supply 16 is distributed, so that some RF power is supplied to the first electrode layer 12aR and flows from the second electrode layer 12bG to the ground via the plasma generated in the plasma processing space 10s. Further, some RF power is supplied to the first electrode layer 12bR and flows from the second electrode layer 12cG to the ground via the plasma generated in the plasma processing space 10s. Furthermore, some RF power is supplied to the first electrode layer 12cR and flows from the second electrode layer 12dG to the ground via the plasma generated in the plasma processing space 10s.

The impedance adjuster 13 may change an amount of radio frequency current flowing from the second electrode layers 12bG, 12cG, and 12dG to the ground. Thus, the diffusion (degree of diffusion), plasma density, or the like of the plasma generated in the plasma processing space 10s may be controlled, which makes it possible to more precisely control the plasma processing of the substrate W.

### Second Embodiment

### [Plasma Processing Apparatus]

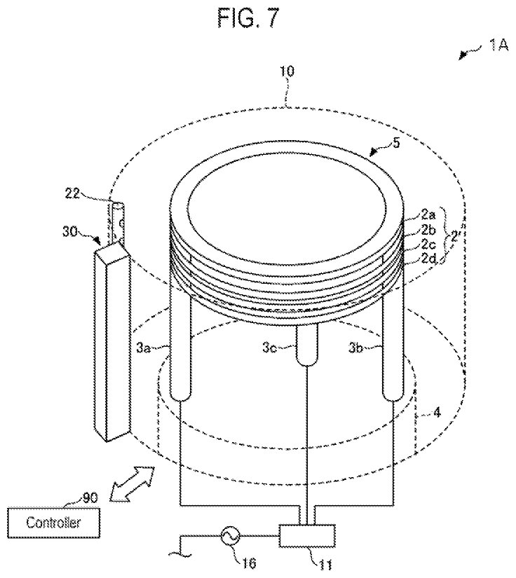

Next, a configuration example of a plasma processing apparatus 1A according to a second embodiment will be described with reference to FIG. 7. FIG. 7 is a schematic diagram illustrating a configuration example of the plasma processing apparatus 1A according to the second embodiment.

The configuration of the plasma processing apparatus 1A according to the second embodiment differs from that of the plasma processing apparatus 1 according to the first embodiment in that the second embodiment is provided with a plasma generation mechanism 30 but such a configuration does not exist in the first embodiment. Thus, the following description will be centered on the plasma generation mechanism 30, and redundant explanations of the configuration described in the first embodiment will be omitted.

The plasma generation mechanism 30 is arranged on the outer sidewall of the processing container 10, includes a counter electrode to which RF power is supplied, and functions as a remote plasma source that generates plasma within the plasma generation mechanism 30. The plasma generation mechanism 30 plasmarizes, for example, a N₂ gas to generate active species such as N radicals.

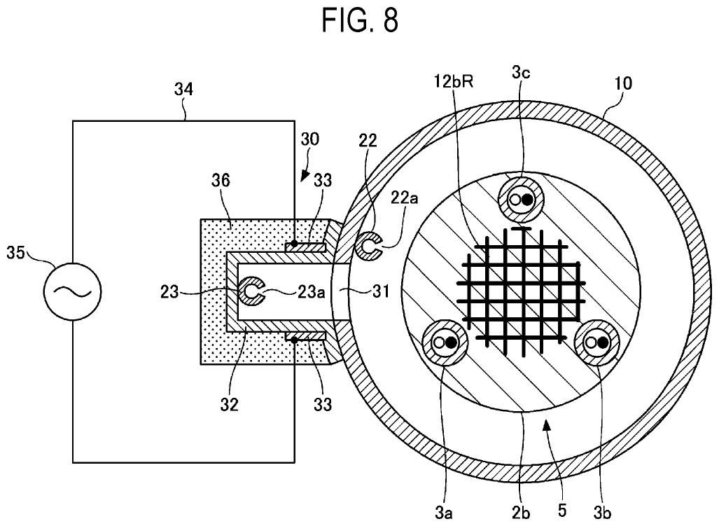

An example of an internal configuration of the plasma generation mechanism 30 will be described with reference to FIG. 8. FIG. 8 is a cross-sectional view of the plasma processing apparatus of FIG. 7 taken in the horizontal direction, and includes a cross-sectional configuration of the plasma generation mechanism 30. The plasma generation mechanism 30 includes a plasma partition wall 32, a pair of plasma electrodes (counter electrodes) 33, a feeder line 34, an RF power supply 35, and an insulating protective cover 36.

The plasma partition wall 32 is hermetically welded to the outer wall of the processing container 10. The plasma partition wall 32 is made of, for example, quartz. The plasma partition wall 32 has a recessed cross sectional shape, and covers an opening 31 formed in the sidewall of the processing container 10. The opening 31 is elongated in the vertical direction so as to cover all substrates W supported in the substrate holder 5 in the vertical direction. A gas supply pipe 23 is arranged in an inner space, that is, a plasma generation space which is defined by the plasma partition wall 32 and communicates with the interior of the processing container 10. On the other hand, the gas supply pipe 22 is provided at a position close to the substrate W along the inner sidewall of the processing container 10 outside the plasma generation space.

The pair of plasma electrodes 33 each have an elongated shape in the height direction of the processing container 10, and are arranged to face each other along the vertical direction on opposite outer surfaces of the plasma partition wall 32. The feeder line 34 is connected to the lower end of each plasma electrode 33.

The feeder line 34 electrically connects each plasma electrode 33 and the RF power supply 35. The RF power supply 35 is connected to the lower end of each plasma electrode 33 via the feeder line 34, and supplies, for example, RF power of 13.56 MHz to the pair of plasma electrodes 33. Thus, the RF power is applied into the plasma generation space defined by the plasma partition wall 32.

A gas (for example, N₂ gas) discharged from a gas hole 23a of the gas supply pipe 23 is plasmarized in the plasma generation space to which the RF power is applied, and active species of the gas thus generated are supplied to the interior of the processing container 10 through the opening 31. The insulating protective cover 36 is provided outside the plasma partition wall 32 so as to cover the plasma partition wall 32.

With the plasma processing apparatus 1A according to the second embodiment, the gas (for example, N₂ gas) may be dissociated in the plasma generation mechanism 30, so that active species such as the N₂ gas may be supplied from the plasma generation mechanism 30 into the processing container 10. In the substrate holder 5, plasma is generated in the plasma processing space 10s between the respective stages 2. For example, a gas supplied from the gas hole 22a of the gas supply pipe 22 (for example, SiH₄ gas) may be dissociated, and active species such as the N₂ gas supplied from the plasma generation mechanism 30 may be re-dissociated in the plasma processing space 10s. Thus, a more precise plasma processing may be performed on the substrate W.

As described above, with the plasma processing apparatuses 1 and 1A according to the first and second embodiments, the first electrode layer 12R that supplies RF power and the second electrode layer 12G that serves as a ground electrode are configured with a metal mesh, and these metal layers are sealed with the stage 2 formed as a quartz plate. That is, two electrode layers are embedded in the stage 2 formed as one quartz plate, so that, for example, RF power is supplied to the first electrode layer 12R at one side and the second electrode layer 12G at the other side is set to the ground potential. By stacking the stages 2 having such a structure one above another, it is possible to provide the batch type plasma processing apparatuses 1 and 1A in which a plurality of stages 2 formed as quartz plates are arranged in a multi-stage structure in the height direction.

In a plasma processing method performed in the plasma processing apparatuses 1 and 1A having such a configuration, RF power is supplied to the first electrode layer 12R, and the second electrode layer 12G is connected to a ground. Plasma is generated in the plasma processing space 10s between the plurality of stages 2 arranged in a multi-stage structure in the substrate holder 5, so that a plurality of substrates W held by the substrate holder 5 are subjected to the plasma processing. Thus, in the batch type plasma processing apparatuses 1 and 1A capable of simultaneously processing the plurality of substrates W, it is possible to more precisely perform the plasma processing on the substrates W, which may improve productivity.

According to the present disclosure in some embodiments, it is possible to more precisely perform a plasma processing on substrates in a batch type plasma processing apparatus.

The plasma processing apparatuses and the plasma processing method according to the embodiments disclosed herein should be considered to be exemplary and not limitative in all respects. The embodiment may be modified and improved in various forms without departing from the scope of the appended claims and their gist. The matters described in the aforementioned embodiments may have other configurations to the extent that they are not contradictory, and may be combined to the extent that they are not contradictory.

What is claimed is:

1. A plasma processing apparatus comprising:
a substrate holder configured to place a plurality of substrates in a multi-stage structure in a height direction on the substrate holder; and
a processing container in which the substrate holder is accommodated and including a heating part that heats the plurality of substrates,
wherein the substrate holder includes a plurality of stages, which are made of a dielectric material, and a first electrode layer and a second electrode layer embedded in the plurality of stages.

2. A plasma processing apparatus comprising:
a substrate holder configured to place a plurality of substrates in a multi-stage structure in a height direction on the substrate holder;
a processing container in which the substrate holder is accommodated and including a heating part that heats the plurality of substrates; and
a plasma generation mechanism arranged on an outer sidewall of the processing container to generate plasma and including a counter electrode to which radio frequency power is supplied,
wherein the substrate holder includes a plurality of stages, which are made of a dielectric material, and a first electrode layer and a second electrode layer embedded in the plurality of stages.

3. The plasma processing apparatus of claim 1, wherein at least one of the first electrode layer and the second electrode layer has a mesh shape or a film shape.

4. The plasma processing apparatus of claim 3, wherein, when the at least one of the first electrode layer and the second electrode layer has the mesh shape, a dielectric pillar is arranged to pass through a gap in the mesh shape.

5. The plasma processing apparatus of claim 1, wherein the radio frequency power is supplied to the first electrode layer, and the second electrode layer is connected to a ground.

6. The plasma processing apparatus of claim 5, wherein the second electrode layer is connected to the ground via an impedance adjuster.

7. The plasma processing apparatus of claim 5, wherein the first electrode layer in a first stage among the plurality of stages faces the second electrode layer in a second stage adjacent to the first stage with a plasma processing space interposed between the first electrode layer and the second electrode layer, and the second electrode layer in the first stage faces the first electrode layer in a third stage adjacent to the first stage with the plasma processing space interposed between the second electrode layer and the first electrode layer, and
wherein the substrate holder is configured to generate plasma in the plasma processing space between the first stage and the second stage and between the first stage and the third stage, and perform a plasma processing on the plurality of substrates when the radio frequency power is supplied to the first electrode layers in the first stage and in the third stage.

8. The plasma processing apparatus of claim 1, wherein the substrate holder includes a lift pin mechanism configured to transfer the plurality of substrates to the plurality of stages, respectively.

9. The plasma processing apparatus of claim 1, wherein each of the plurality of stages of the substrate holder has a placement surface on which the substrate is placed.

10. The plasma processing apparatus of claim 9, wherein the first electrode layer and the second electrode layer have circular outer edges, and the circular outer edges of the first electrode layer and the second electrode layer are larger than or the same as an outer edge of the placement surface.

11. The plasma processing apparatus of claim 10, wherein the outer edge of the first electrode layer and the outer edge of the second electrode layer have the same size.

12. The plasma processing apparatus of claim 9, wherein the substrate holder includes a plurality of hollow post members made of the dielectric material and provided to extend in the height direction at an outer peripheral side of the placement surface.

13. The plasma processing apparatus of claim 12, wherein a ground line connected to the second electrode layer in the plurality of stages is accommodated in at least one of the plurality of hollow post members.

14. The plasma processing apparatus of claim 12, further comprising: a radio frequency power supply configured to output radio frequency power,
wherein a feeder line that connects the radio frequency power supply and the first electrode layer in the plurality of stages is accommodated in at least one of the plurality of hollow post members.

15. The plasma processing apparatus of claim 12, wherein an inner wall of the plurality of hollow post members is covered with a metal film or a metal cylindrical member, and
wherein the metal film or the metal cylindrical member is connected to a ground and functions as a ground line that grounds the second electrode layer in the plurality of stages.

16. The plasma processing apparatus of claim 1, comprising:
a radio frequency power supply configured to output a radio frequency power; and
a distributor configured to distribute the radio frequency power output from the radio frequency power supply,
wherein the radio frequency power is distributed and supplied to a plurality of first electrode layers in the plurality of stages.

17. The plasma processing apparatus of claim 1, wherein, among the plurality of stages, the second electrode layer is arranged above the first electrode layer in the plurality of stages.

18. The plasma processing apparatus of claim 1, wherein uppermost and lowermost electrode layers among the first electrode layer and the second electrode layer embedded in the plurality of stages are the second electrode layer.

19. A plasma processing method performed in the plasma processing apparatus of claim 1, the plasma processing method comprising:
supplying radio frequency power to the first electro de layer;
connecting the second electrode layer to a ground; and
generating plasma in a space between the plurality of stages arranged in the multi-stage structure in the substrate holder to perform a plasma processing on the plurality of substrates held by the substrate holder.

20. A plasma processing method performed in the plasma processing apparatus of claim 2, the plasma processing method comprising:
supplying radio frequency power to the first electrode layer;
connecting the second electrode layer to a ground; and
generating plasma in a space between the plurality of stages arranged in the multi-stage structure in the substrate holder to perform a plasma processing on the plurality of substrates held by the substrate holder.
